(19) United States
(12) Patent Application Publication
(10) Pub. No.: US 2010/0032740 A1
(43) Pub. Date: Feb. 11, 2010

(54) Semiconductor device and method of manufacturing the same

(75) Inventor: Hiroyasu Kitajima, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/458,335

(22) Filed: Jul. 8, 2009

(30) Foreign Application Priority Data
Aug. 7, 2008 (JP) 2008-204062

(51) Int. Cl. H01L 27/108; H01L 21/02

(52) U.S. Cl. 257/296; 438/386; 257/E27.084; 257/E21.008

(57) ABSTRACT

A semiconductor device that enables placement of a line or the like under a fuse without any additional step and a method of manufacturing the same are provided. The semiconductor device includes a plurality of first capacitor holes made in an insulating layer, a capacitor formed in the first capacitor holes, a DRAM cell made up of the capacitor and a transistor coupled to the capacitor, a plurality of second capacitor holes made in the insulating layer, and a fuse formed between the second capacitor holes.

### BACKGROUND

1. Field of the Invention

The present invention relates to a semiconductor device including dynamic random access memory (DRAM) and, particularly, to a semiconductor device including a fuse for replacing a defective bit of a memory cell.

2. Description of Related Art

With a development of an ultra-large-scale integration semiconductor device, a change in wiring material from Al to Cu, which is a low resistance material, is becoming essential. In order to realize high-speed operation, it is necessary to reduce the capacitance between Cu wiring layers, and a low dielectric constant (low-k) material film may be used as an interlayer insulating film for this purpose. However, a Cu wiring and a low-k film have low moisture resistance, and in the case of using Cu as a fuse material, moisture enters through a laser cut portion to cause a corrosion of an adjacent fuse, which raises an issue of erroneous decision. On the other hand, if an Al wiring layer is added to place a fuse, it results in cost increase.

In order to address the above issue, it is necessary to form a fuse by using a wiring layer at the uppermost layer possible that is not an Al line or a Cu line. For example, a structure of forming a fuse in an upper wiring layer is disclosed in Japanese Unexamined Patent Publications Nos. 10-150164 and 2006-228792.

FIG. 19 is a cross-sectional view showing the structure of a semiconductor device disclosed in Japanese Unexamined Patent Publication No. 10-150164. The right side of FIG. 19 shows a cell part, and the left side shows a fuse part. As shown in the right side part of FIG. 19, a capacitor is formed by a second conductive layer 192 of an upper electrode, an insulating film 193 and a first conductive layer 191 of a lower electrode. Further, in the fuse part shown in the left side of FIG. 19, a fuse made of the second conductive layer 192 is formed by the same material and in the same step as the upper electrode 192 of the capacitor element.

FIG. 20 is a cross-sectional view showing the structure of a semiconductor device disclosed in Japanese Unexamined Patent Publication No. 2006-228792. Japanese Unexamined Patent Publication No. 2006-228792 discloses a technique of placing a conductive layer 202 to form a fuse 202a at the uppermost layer possible so as to prevent damage below the fuse caused by fuse cut. Thus, a signal line or the like can be placed below the fuse 202a.

### SUMMARY

The present inventors, however, have found a problem that, in the semiconductor device disclosed in Japanese Unexamined Patent Publication No. 10-150164, a layer placed below the fuse is damaged by laser cut of the fuse, thus allowing formation of no element in the lower layer of the fuse in terms of reliability.

Further, the present inventors have found a problem that, in the semiconductor device disclosed in Japanese Unexamined Patent Publication No. 2006-228792, it is necessary to form an insulating layer 201 for lifting the fuse 202a to a higher level in order to form the conductive layer 202 to serve as the fuse 202a in an upper layer, thus requiring an additional step of forming the insulating layer.

A first exemplary aspect of an embodiment of the present invention is a semiconductor device including a dynamic random access memory (DRAM) cell and a fuse that comprises an insulating layer having a plurality of first capacitor holes and a plurality of second capacitor holes, a capacitor function as the DRAM cell formed in the first capacitor holes, and a fuse formed between the second capacitor holes.

According to the exemplary aspect of an embodiment of the present invention, a conductive layer formed between the second capacitor holes is used as a fuse, thereby absorbing damage by fuse cut with the thickness of the insulating layer in which the first and second capacitor holes are made. It is thereby possible to place a circuit element or the like under the fuse without adding an insulating layer, which enables reduction of a chip size.

A second exemplary aspect of an embodiment of the present invention is a method of manufacturing a semiconductor device that includes forming an insulating layer on a semiconductor substrate, making first capacitor holes and second capacitor holes in the insulating layer, forming a capacitor in the first capacitor holes, and forming a fuse by forming a conductive layer between the second capacitor holes.

According to the method of manufacturing a semiconductor device of the exemplary aspect of an embodiment of the present invention, the second capacitor holes are made in the insulating layer in which the first capacitor holes are made, and the fuse is formed between the second capacitor holes, so that damage by fuse cut is absorbed with the thickness of the insulating layer in which the first and second capacitor holes are made. It is thereby possible to place a circuit element or the like under the fuse without adding an insulating layer.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a plan view showing the overall structure of a semiconductor device according to a first exemplary embodiment of the present invention;

FIG. 2 is a plan view of a cell part in the semiconductor device according to the first exemplary embodiment of the present invention;

FIG. 3 is a cross-sectional view along line III-III in FIG. 2;

FIG. 4 is a plan view of a fuse part in the semiconductor device according to the first exemplary embodiment of the present invention;

FIG. 5 is a cross-sectional view along line V-V in FIG. 4;

FIGS. 6A to 6D are cross-sectional views showing a manufacturing process of the semiconductor device according to the first exemplary embodiment of the present invention;

FIGS. 7A to 7C are cross-sectional views showing a manufacturing process of the semiconductor device according to the first exemplary embodiment of the present invention;

FIGS. 8A and 8B are cross-sectional views showing a manufacturing process of the semiconductor device according to the first exemplary embodiment of the present invention;

FIGS. 9A and 9B are cross-sectional views showing a manufacturing process of the semiconductor device according to the first exemplary embodiment of the present invention;

FIGS. 10A and 10B are cross-sectional views showing a manufacturing process of the semiconductor device according to the first exemplary embodiment of the present invention;

FIGS. 11A and 11B are cross-sectional views showing a manufacturing process of the semiconductor device according to the first exemplary embodiment of the present invention;

FIG. 12 is a schematic view showing advantages of the semiconductor device according to the first exemplary embodiment of the present invention;

FIG. 13 is a plan view of a semiconductor device according to a second exemplary embodiment of the present invention;

FIG. 14 is a cross-sectional view along line XIV-XIV in FIG. 13;

FIG. 15 is a plan view of a semiconductor device according to a third exemplary embodiment of the present invention;

FIG. 16 is a cross-sectional view along line XVI-XVI in FIG. 15;

FIG. 17 is a plan view of a semiconductor device according to a fourth exemplary embodiment of the present invention;

FIG. 18 is a cross-sectional view along line XVIII-XVIII in FIG. 17;

FIG. 19 is a cross-sectional view showing the structure of a semiconductor device disclosed in Japanese Unexamined Patent Publication No. 10-150164; and

FIG. 20 is a cross-sectional view showing the structure of a semiconductor device disclosed in Japanese Unexamined Patent Publication No. 2006-228792.

### DETAILED DESCRIPTION OF THE EXEMPLARY EMBODIMENTS

Preferred exemplary embodiments of the present invention are described hereinafter with reference to the drawings.

### First Exemplary Embodiment

A semiconductor device according to a first exemplary embodiment of the present invention is described hereinafter, taking dynamic random access memory (DRAM) as an example. The present invention, however, is not limited to DRAM and may be applied to various kinds of semiconductor devices including fuses.

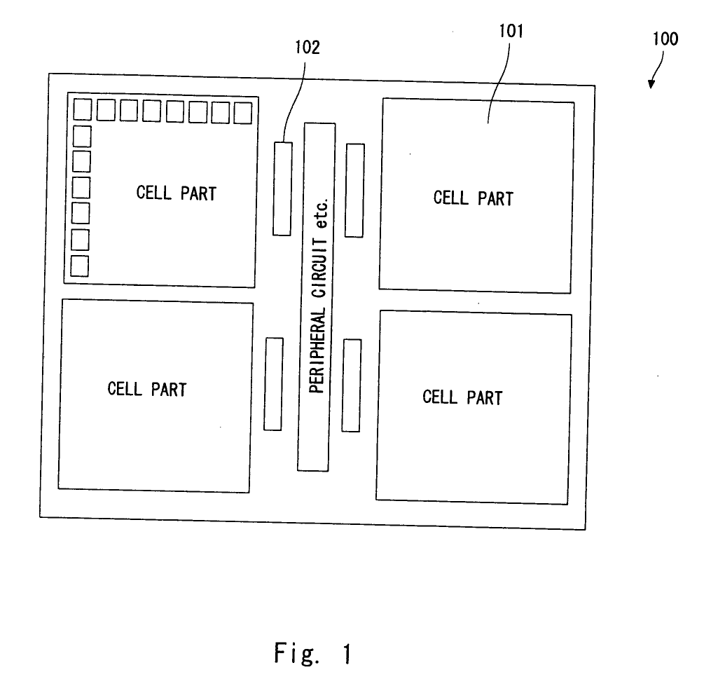

FIG. 1 is a plan view showing the overall structure of a semiconductor device according to the first exemplary embodiment of the present invention. A semiconductor device 100 includes a cell part 101 in which memory cells are formed in matrix, and a fuse part 102 in which fuses are formed. The fuses are connected to signal lines or the like formed in the cell part 101 to switch connection of the lines. In the following description, the fuse part 102 is a fuse for switching connection of a bit line. As shown in FIG. 1, the fuse part 102 is formed in a different area from the cell part 101. In the semiconductor device 100, a peripheral circuit controlling received and output data, an electrode pad performing input/output port of data or the like, for example, are formed at the center of a chip.

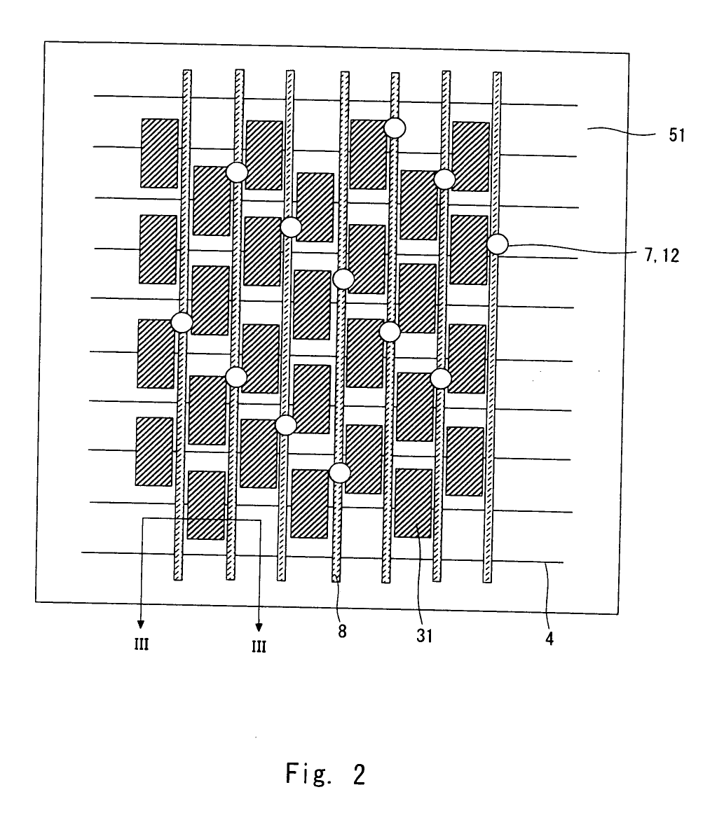

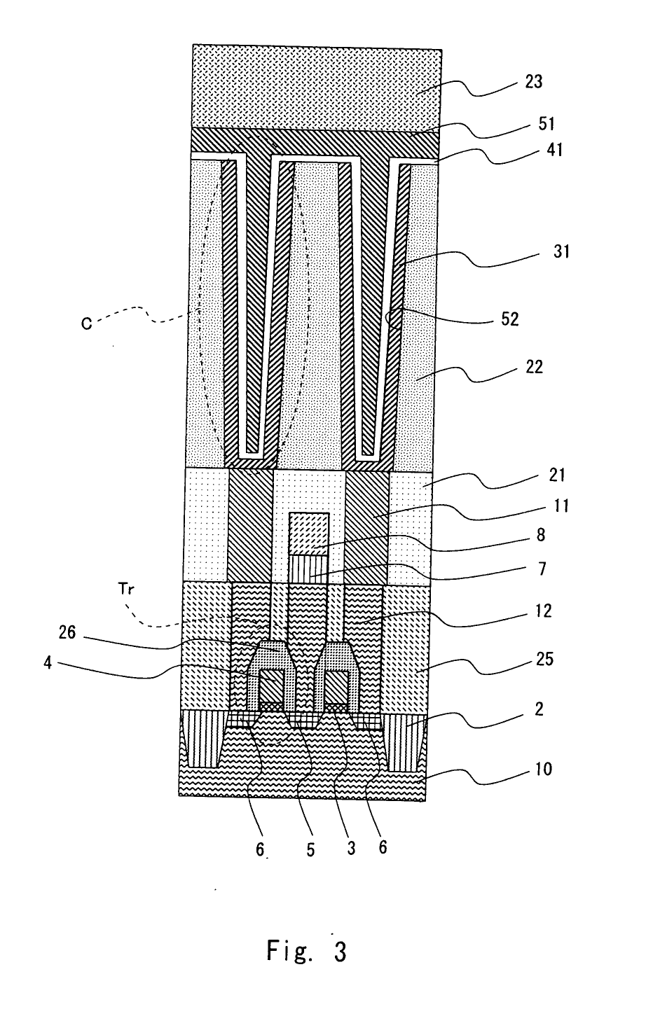

FIG. 2 is a plan view of the cell part in the semiconductor device according to the first exemplary embodiment of the present invention, and FIG. 3 is a cross-sectional view along line III-III in FIG. 2. In FIG. 2, the illustration of a fourth interlayer insulating film 23 in FIG. 3 is omitted for convenience of description. In the cell part 101, capacitors C accumulating electric charge as data and switching transistors Tr are formed. The sectional view of FIG. 3 shows two switching transistors Tr connected to a common bit line 8 and two capacitors C connected to the respective switching transistors Tr.

A first diffusion region 5 and a second diffusion region 6 of a semiconductor substrate 10 serves as source and drain regions of the switching transistor Tr respectively. The first diffusion region 5 is placed between the adjacent second diffusion regions 6. The first diffusion region 5 is shared by the adjacent two switching transistors Tr. Further, an isolation insulating film 2 for electrically isolating the adjacent diffusion regions is formed on the left side and right side of the set of second diffusion regions 6 of the switching transistor Tr.

A first interlayer insulating film 25 is formed on the semiconductor substrate 10. A gate electrode 4 is formed above a channel region between the first diffusion region 5 and the second diffusion region 6 with a gate insulating film 3 interposed therebetween. A side wall insulating film 26 is formed to cover the outside of the gate electrode 4. Further, contact plugs 12 for connecting the first diffusion region 5 and the second diffusion region 6 to a lead line in the upper layer is formed in the first interlayer insulating film 25.

A second interlayer insulating film 21 is formed on the first interlayer insulating film 25. In the position corresponding to the first diffusion region 5, a bit line 8 is formed. The bit line 8 is electrically connected to the first diffusion region 5 of the semiconductor substrate 10 through a contact plug 7 and the contact plug 12 in the lower layer. In other words, the contact plugs 7 and 12 connected to the bit line 8 function as a part of the bit line 8. In the second interlayer insulating film 21, a contact plug 11 for connecting the second diffusion region 6 to a conductive layer in the upper layer is formed in the position corresponding to each of the second diffusion regions 6.

A third interlayer insulating film 22 is formed on the second interlayer insulating film 21. The thickness of the third interlayer insulating film 22 is set so as to ensure a sufficient amount of capacitance of the capacitors C. In the third interlayer insulating film 22, a first capacitor hole 52 that reaches the second interlayer insulating film 21 is made in the position corresponding to the second diffusion region 6. On the bottom and side surfaces of the first capacitor hole 52, a first conductive layer 31 is formed along the first capacitor hole 52. In the cell part 101, the first conductive layer 31 functions as the lower electrode of the capacitor C. The first conductive layer 31 is connected to the contact plug 11 of the second interlayer insulating film 21 at the bottom of the first capacitor hole 52. A capacitor insulating film 41 is formed on the first conductive layer 31 and the third interlayer insulating film 22.

A second conductive layer 51 is formed inside the first capacitor hole 52 and above the third interlayer insulating film 22 with the capacitor insulating film 41 interposed therebetween. In the cell part 101, the second conductive layer 51 functions as the upper electrode of the capacitor C. The capacitor C is formed with the first conductive layer 31 serving as the lower electrode, the capacitor insulating film 41 and the second conductive layer 51 serving as the upper electrode. The second conductive layer 51 is formed inside the first capacitor hole 52 and above the third interlayer insulating film 22 between the adjacent first capacitor holes 52. The capacitor C is made up of the first conductive layer (lower electrode) 31, the capacitor insulating film 41 and the second conductive layer (upper electrode) 51. A fourth interlayer insulating film 23 is formed on the second conductive layer 51.

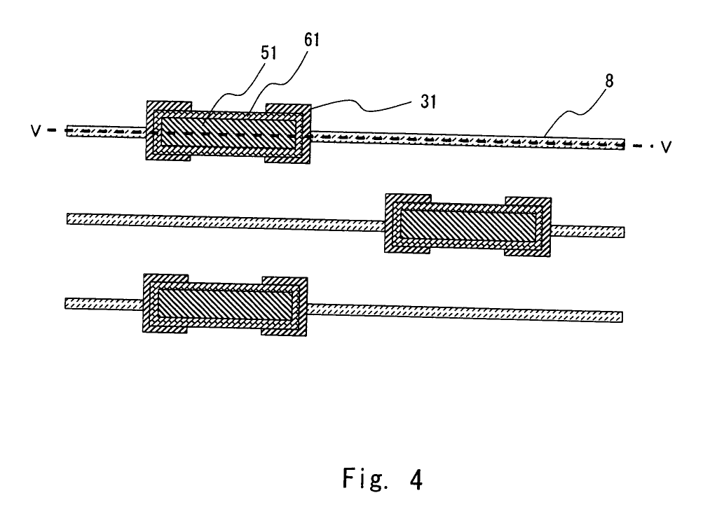

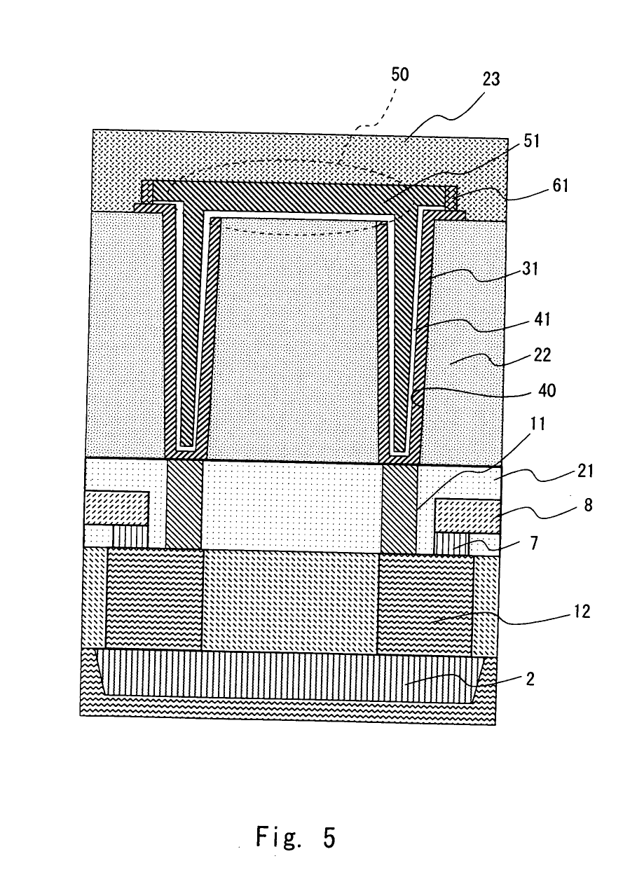

FIG. 4 is an enlarged plan view of the fuse part 102 in the semiconductor device according to the first exemplary embodiment of the present invention, and FIG. 5 is a cross-sectional view along line V-V in FIG. 4. The cross-sectional shape of the fuse part 102 has substantially the same structure as the cross-sectional shape of the cell part 101.

The semiconductor device includes a plurality of first capacitor holes 52 (cf. FIG. 3) made in an insulating layer (the third interlayer insulating film 22), the capacitors C formed in the first capacitor holes 52, a DRAM cell composed of the capacitors C and the transistors Tr coupled to the capacitors C, a plurality of second capacitor holes 40 made in the insulating layer (the third interlayer insulating film 22), and a fuse 50 (cf. FIG. 4) formed between the second capacitor holes 40.

The same elements as in the cell part 101 shown in FIGS. 2 and 3 are denoted by the same reference symbols. As shown in FIG. 5, the isolation insulating film 2 is formed in the semiconductor substrate 10. The isolation insulating film 2 is configured to prevent the adjacent contact plugs 12 formed in the upper layer from being electrically connected to each other through the semiconductor layer. The contact plug 12 penetrating the first interlayer insulating film 25 is formed in the first interlayer insulating film 25. In the fuse part 102, the contact plug 12 functions as a part of a routing line for connecting the bit line 8 to the fuse 50 in the upper layer.

The bit line 8 is formed in the second interlayer insulating film 21. The bit line 8 is connected to the contact plug 12 in the lower layer through the contact plug 7. Further, in the second interlayer insulating film 21, the contact plug 11 is formed in the position corresponding to the contact plug 12. Thus, in the fuse part 102, the contact plugs 7, 12 and 11 function as a part of the routing line of the fuse 50 which is placed in the bit line 8. The bit line 8 is routed to a decision circuit, which is not shown. Such a routing line of the fuse 50 is formed in the lower layer of the fuse 50.

The third interlayer insulating film 22 is formed on the second interlayer insulating film 21. The second capacitor holes 40 are made in the third interlayer insulating film 22. The second capacitor holes 40 are made in the same step as the first capacitor holes 52 of the cell part 101, as described later. However, the interval between the second capacitor holes 40 of the fuse part 102 is larger than the interval between the first capacitor holes 52 of the cell part 101 in order to ensure a sufficient length for fuse cut. The first conductive layer 31 is formed on the side and bottom surfaces of the second capacitor holes 40. The first conductive layer 31 is formed to extend onto the third interlayer insulating film 22.

The capacitor insulating film 41 is formed to cover the first conductive layer 31 and the third interlayer insulating film 22. Further, the second conductive layer 51 is formed inside the second capacitor holes 40 and above the third interlayer insulating film 22. The second conductive layer 51 is formed to fill the second capacitor holes 40. The second conductive layer 51 is formed inside the second capacitor holes 40 and across the adjacent second capacitor holes 40. In other words, one end of the second conductive layer 51 extends to cover the opening of one second capacitor hole 40, and the other end of the second conductive layer 51 extends to cover the opening of the other second capacitor hole 40. In the flat part between the second capacitor holes 40, the second conductive layer 51 is laser cut when switching connection of the bit line. That is, the second conductive layer 51 formed in flat part between the capacitor holes serves as the fuse 50.

In the fuse part 102, a third conductive layer 61 for connecting the first conductive layer 31 and the second conductive layer 51 is formed at the ends of the first conductive layer 31 and the second conductive layer 51. The first conductive layer 31 thereby functions as a lead line of the fuse 50 (the second conductive layer 51). The cell part 101 and the fuse part 102 have substantially the same structure except the third conductive layer 61. Further, a fourth interlayer insulating film 23 is formed on the second conductive layer 51. The fuses 50 having such a structure are arranged alternately between the adjacent bit lines 8 as shown in FIG. 4. In other words, the fuses 50 formed in the adjacent bit lines 8 are disposed in a staggered arrangement.

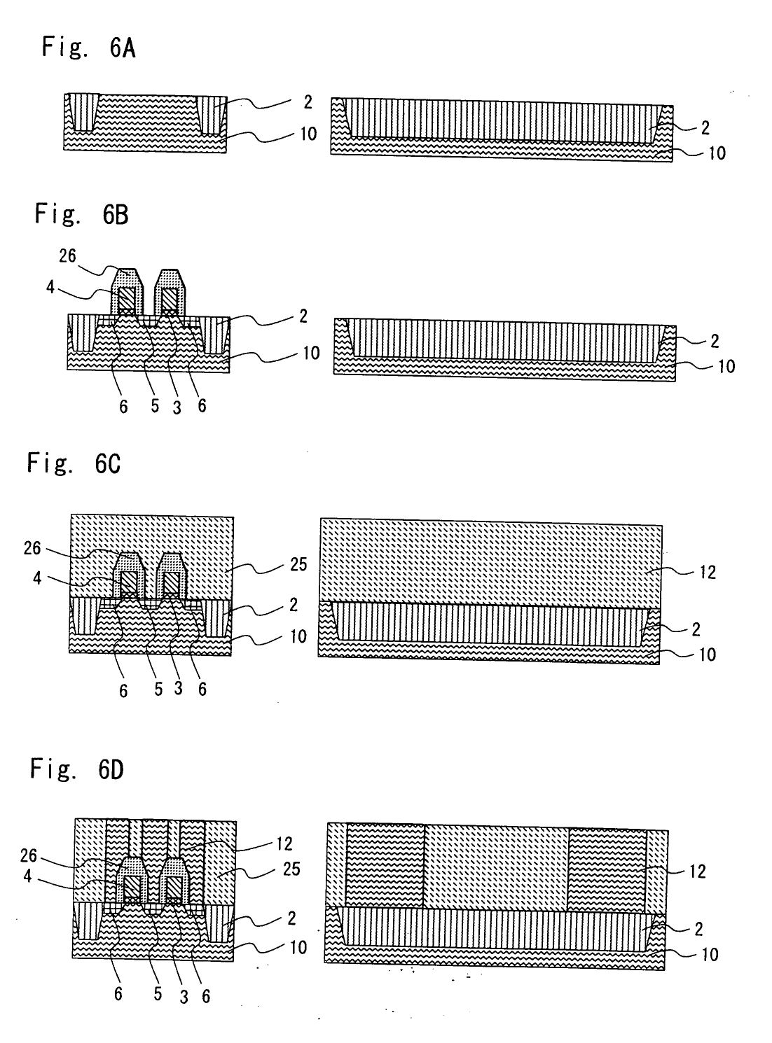

A method of manufacturing the fuse having the above structure is described hereinafter. FIGS. 6A to 11B are cross-sectional views showing the manufacturing process of the fuse according to the first exemplary embodiment of the present invention. The left side and the right side of FIGS. 6A to 11B respectively show the structure of the cell part 101 and the structure of the fuse part 102 in each manufacturing step. Referring first to FIG. 6A, the isolation insulating film 2 is formed in a given position of the semiconductor substrate 10.

Referring next to FIG. 6B, the diffusion regions 5 and 6 are formed in the cell part 101 by doping impurity ions and performing heat treatment. Further, the gate electrode 4 is formed in the position corresponding to the channel region between the first diffusion region 5 and the second diffusion region 6 formed on the semiconductor substrate 10, with the gate insulating film 3 interposed therebetween. Furthermore, the side wall insulating film 26 is formed to cover the gate electrode 4. Referring then to FIG. 6C, the first interlayer insulating film 25 is deposited overall. Referring to FIG. 6D, the contact plug 12 is formed in a given position of the first interlayer insulating film 25.

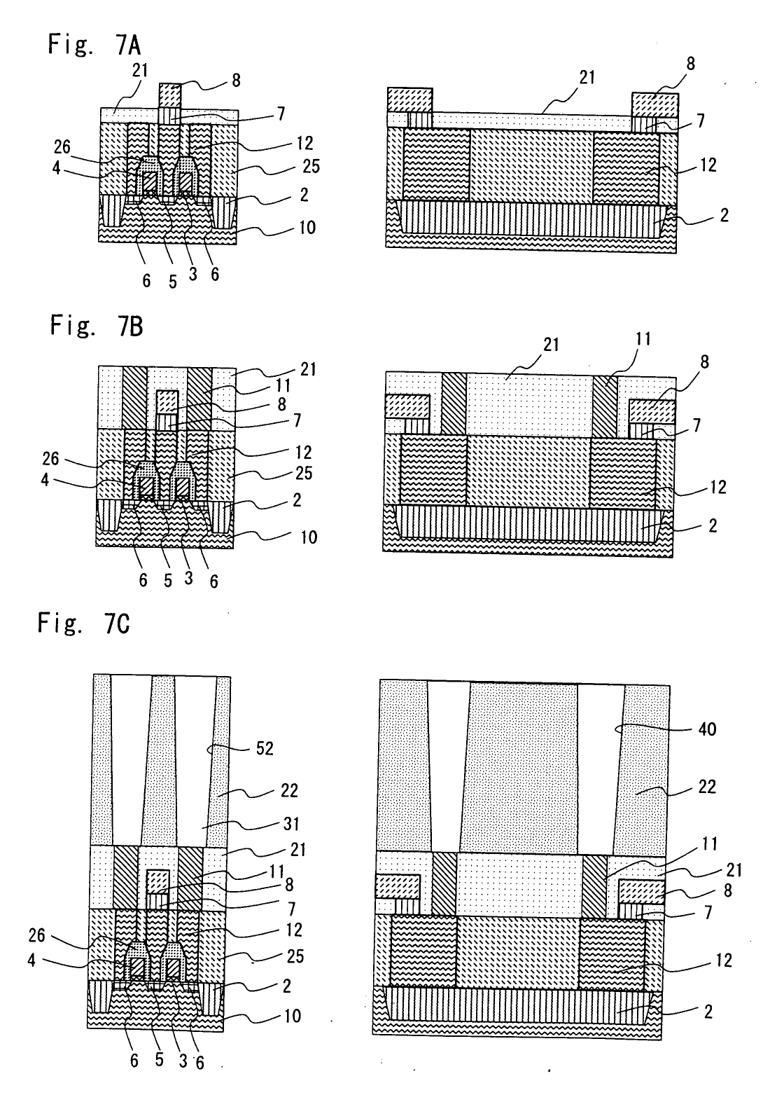

Referring further to FIG. 7A, the second interlayer insulating film 21 is formed on the first interlayer insulating film 25, and the contact plug 7 is formed in the second interlayer insulating film 21. The bit line 8 is formed on top of the contact plug 7. Referring then to FIG. 7B, the second interlayer insulating film 21 is deposited. overall to cover the bit line 8. Further, the contact plug 11 is formed in the position corresponding to the contact plug 12. Referring to FIG. 7C, the third interlayer insulating film 22 is deposited. Then, the first capacitor hole 52 is made in the cell part 101, and further the second capacitor hole 40 is made in the fuse part 102 in the same step. The interval between the first capacitor holes 52 of the cell part 101 is smaller than the interval between the second capacitor holes 40 of the fuse part 102.

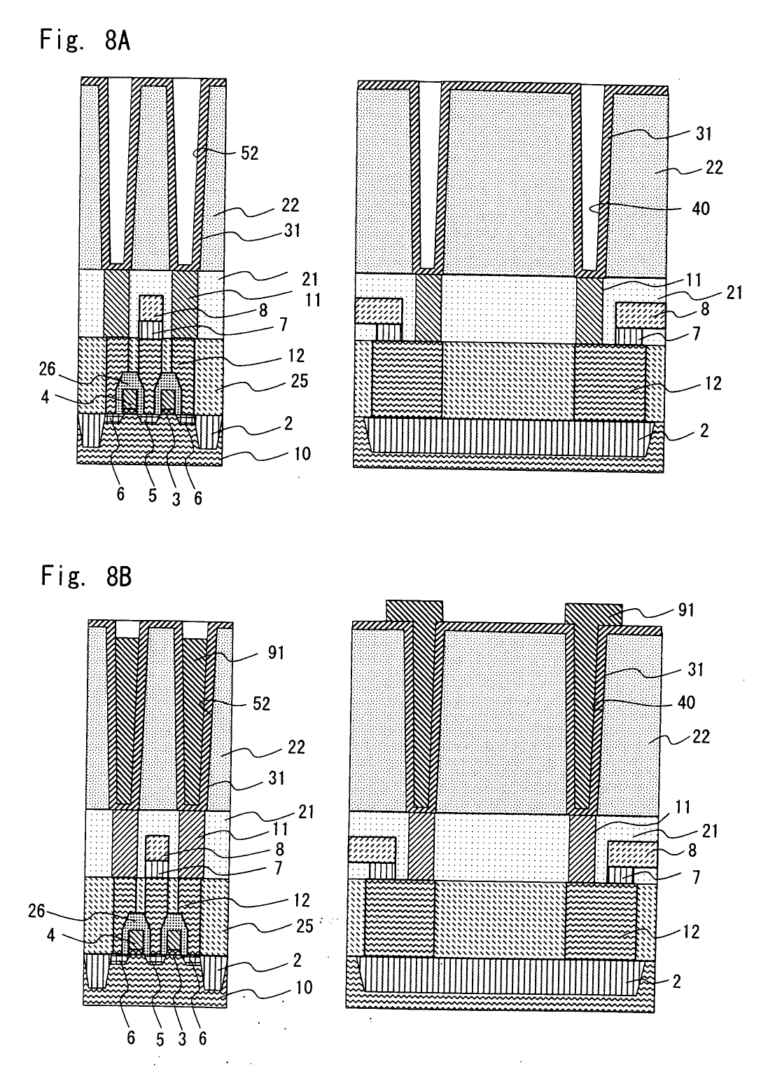

Referring then to FIG. 8A, the first conductive layer 31 to serve as the lower electrode of the cell part 101 is deposited all over the third interlayer insulating film 22 including the inside of the first and second capacitor holes 52 and 40. Referring to FIG. 8B, a photoresist 91 is coated all over the substrate to fill the first and second capacitor holes 52 and 40. In the cell part 101, the photoresist 91 is left only inside the first capacitor hole 52 by performing flood exposure and development. On the other hand, in the fuse part 102, the photoresist 91 is left in the fuse lead part (on the third interlayer insulating film 22) and inside the second capacitor holes 40 by using a mask pattern rather than performing flood exposure in this exemplary embodiment.

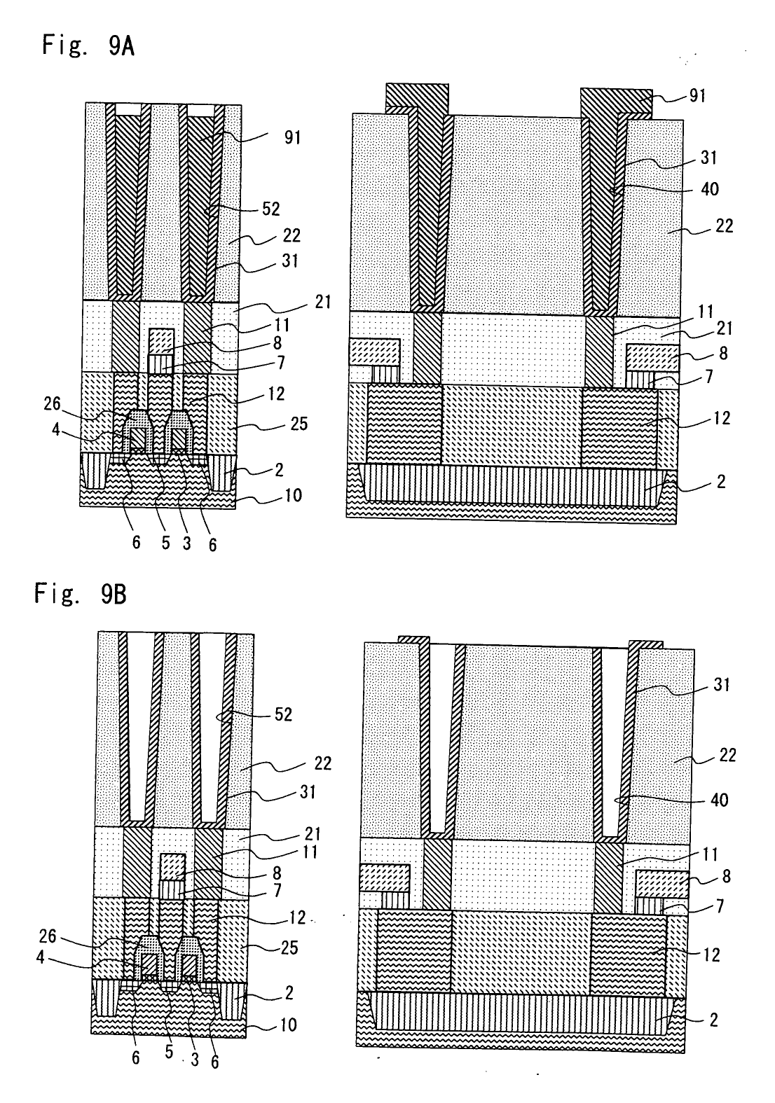

Referring to FIG. 9A, the first conductive layer 31 is separated by etch back. Referring further to FIG. 9B, the photoresist 91 is removed.

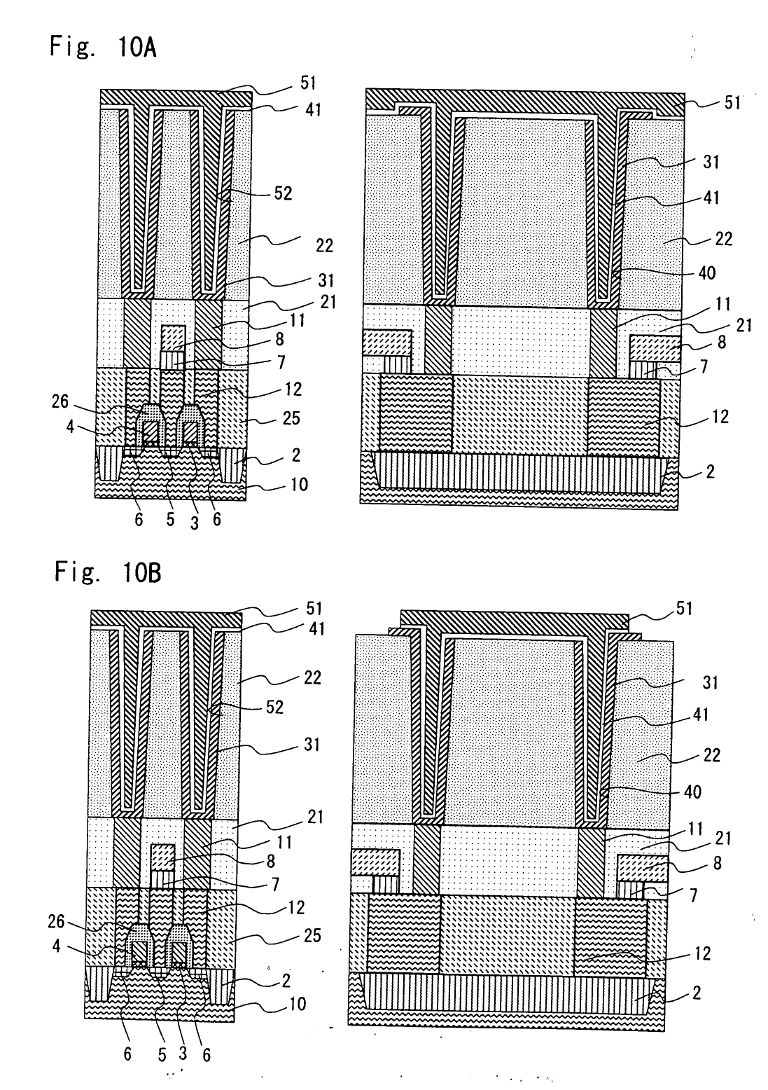

Referring to FIG. 10A, the capacitor insulating film 41 is formed overall by CVD, and the second conductive layer 51 is deposited. Referring to FIG. 10B, the second conductive layer 51 is patterned. In this step, the second conductive layer 51 of the fuse part 102 is patterned so as to overlap the first conductive layer 31.

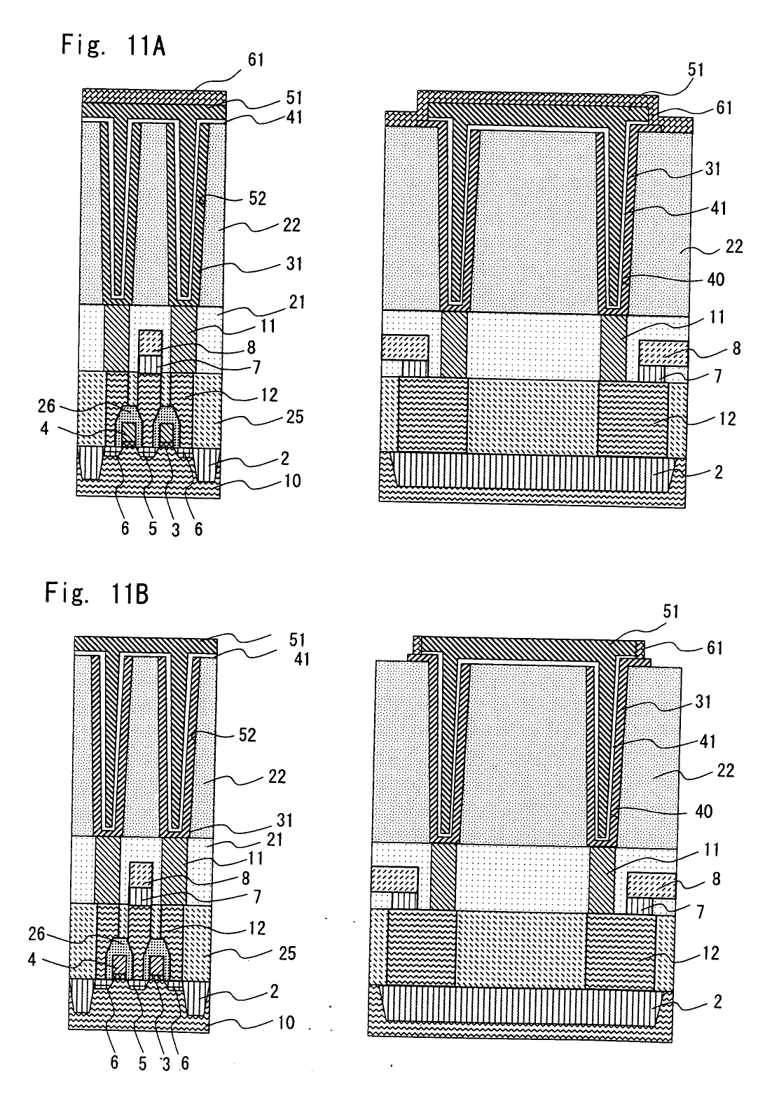

Referring then to FIG. 11A, the third conductive layer 61 is deposited all over the substrate and then etched back. As a result, the third conductive layer 61 that electrically connects the second conductive layer 51 (the upper electrode in the cell part 101) and the first conductive layer 31 (the lower electrode in the cell part 101) is formed in a side-wall shape as shown in FIG. 11B. For the process other than the step of forming the third conductive layer 61, a known manufacturing method may be applied.

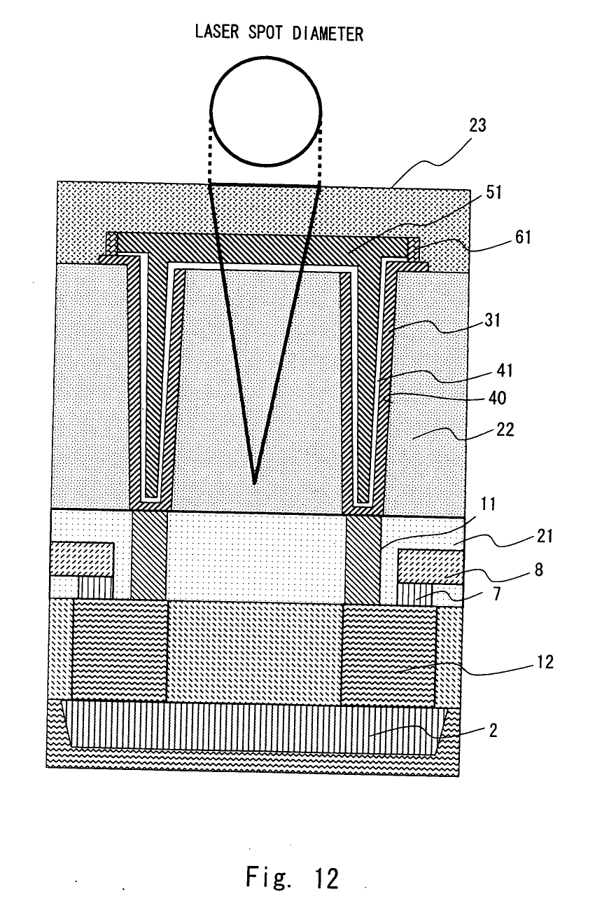

FIG. 12 is a schematic view showing advantages of the semiconductor device according to the first exemplary embodiment of the present invention. As shown in FIG. 12, the area that is damaged by laser cut becomes smaller toward the lower layer. In the semiconductor device according to the first exemplary embodiment, the fuse 50 is formed in the flat part between the second capacitor holes 40, and it is thus possible to prevent damage by fuse cut from reaching the lower layer because of the thickness of the third interlayer insulating film 22 where the capacitor C is formed. Because the thickness of the third interlayer insulating film 22 is set to be at least about 1 μm in order to obtain a sufficient amount of capacitance of the capacitor C, the thickness can be utilized for preventing damage by fuse cut. It is thereby possible to place a line and an element or the like below the fuse. This achieves a higher degree of integration of the semiconductor device. The step of forming the fuse 50 may be performed in substantially the same step as the manufacturing step of the cell part 101.

Further, in the semiconductor device according to the first exemplary embodiment, an outlet (routing line) of the fuse 50 is placed in the lower layer than the fuse 50, and the fuses 50 are disposed in a staggered arrangement (cf. FIG. 4). As described earlier, the area that is damaged by laser cut becomes smaller toward the lower layer. Therefore, in the first exemplary embodiment, the routing line or the like of the adjacent fuses is not damaged by fuse cut compared to the case where the outlet is placed in the upper layer of the fuse as in related art. It is thereby possible to reduce the fuse pitch, thus achieving a higher degree of integration of the semiconductor device. For example, if a laser spot diameter for laser cut is 1 μm, the interval of the bit lines in the fuse part 102 may be 1 μm. Further, because the routing line is placed in the lower layer than the fuse 50, false cut is not likely to occur in this structure.

Furthermore, the second conductive layer 51 (upper electrode) is the uppermost wiring layer excluding an Al line and a Cu line. If the fuse is the lower-layer line as in related art, the number of times to perform chemical mechanical polishing (CMP), which is one of the manufacturing process, increases and thereby the thickness of the insulating film increasingly varies, causing the fuse cut to be unstable. Because the fuse is formed in the upper wiring layer in this exemplary embodiment, it is possible to stably control the thickness of the insulating film above the fuse to be rather thin.

### Second Exemplary Embodiment

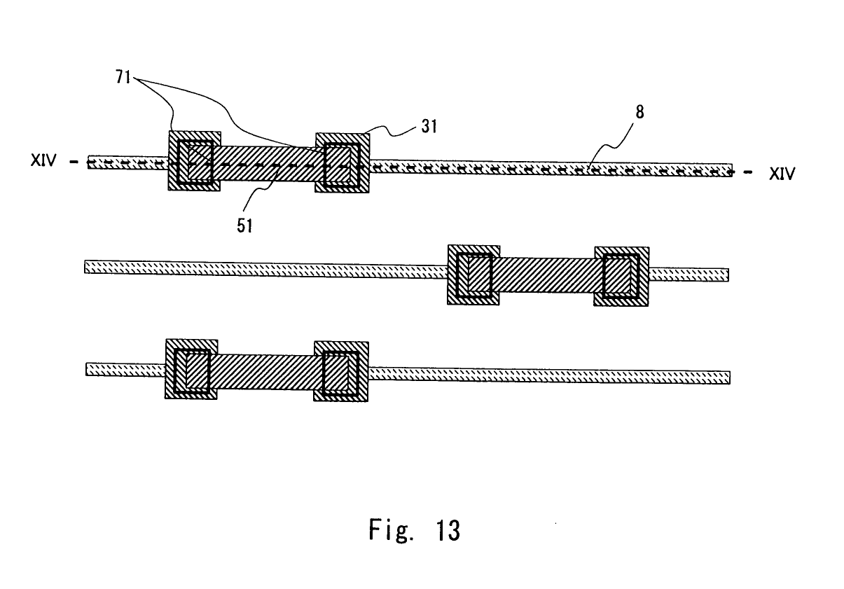

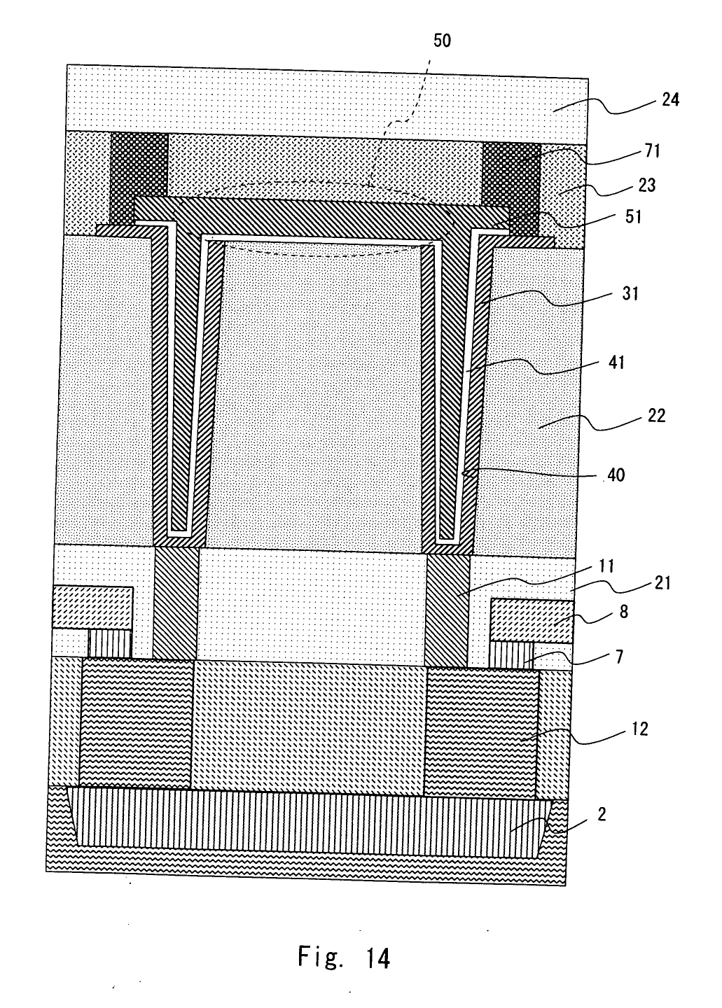

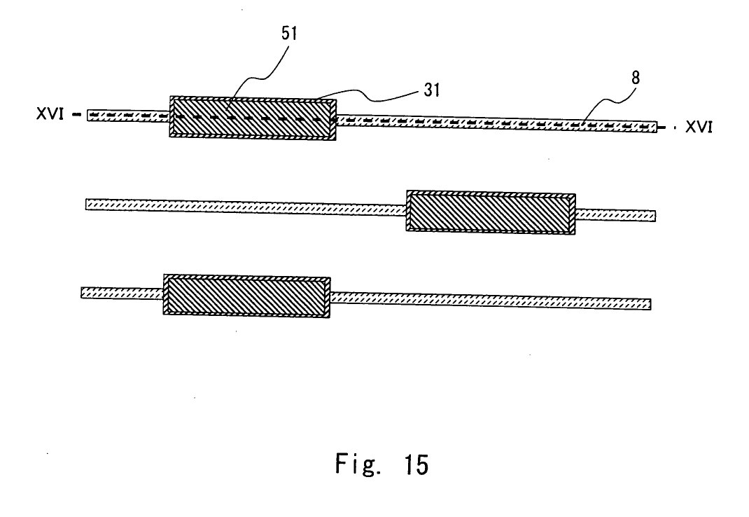

FIG. 13 is a plan view showing a fuse part of a semiconductor device according to a second exemplary embodiment of the present invention, and FIG. 14 is a cross-sectional view along line XIV-XIV in FIG. 13. A feature of the second exemplary embodiment is that the second conductive layer 51 is electrically connected to the first conductive layer 31 through a contact plug 71. In the followings, the elements substantially the same as those in the first exemplary embodiment are denoted by the same reference symbols and not repeatedly described.

The first conductive layer 31 is connected to the contact plug 11 at the bottom. The first conductive layer 31 is further connected to the bit line 8 through the contact plugs 12 and 7 and routed to a decision circuit. The second conductive layer 51 is formed to partly overlap the first conductive layer 31 on the periphery of the opening of the capacitor hole.

The contact plug 71 is formed in the overlapping part of the first conductive layer 31 and the second conductive layer 51, penetrating the fourth interlayer insulating film 23. The contact plug 71 thereby connects the second conductive layer 51 (the upper electrode) and the first conductive layer 31 (the lower electrode). Further, a fifth interlayer insulating film 24 is formed on the fourth interlayer insulating film 23.

A method of manufacturing the semiconductor device having such a structure is described hereinafter. The process up to the step of forming the second interlayer insulating film 21 is the same as that in the first exemplary embodiment and thus not described. Firstly, the third interlayer insulating film 22 is deposited, and the second capacitor holes 40 are made in the same step as the first capacitor holes 52 of the cell part. Then, the first conductive layer 31 to serve as the lower electrode is deposited, and a photoresist is coated all over the substrate to fill the second capacitor holes 40. Although the photoresist is generally left only inside the capacitor hole by performing flood exposure and development, the photoresist is left in the fuse lead part and inside the second capacitor holes 40 by using a mask pattern rather than performing flood exposure in this exemplary embodiment. After that, the first conductive layer 31 (the lower electrode) is separated by etch back.

Then, the capacitor insulating film 41 is formed by CVD, and the second conductive layer 51 to serve as the upper electrode is deposited and patterned. The second conductive layer 51 of the fuse part is patterned so as to overlap the first conductive layer 31.

Further, the fourth interlayer insulating film 23 is deposited on the second conductive layer 51 and planarized. In the fourth interlayer insulating film 23, a contact hole is made by patterning so as to overlap the boundary between the first conductive layer 31 and the second conductive layer 51 in the fuse part. The contact hole is then filled with a conductive layer, and planarization is made by CMP, etch back or the like, thereby forming the contact plug 71 that connects the first conductive layer 31 and the second conductive layer 51. The step of forming the contact plug 71 is the same as the step of forming the contact plug for connecting the gate electrode 4, the diffusion regions 5 and 6, the bit line 8 or the first conductive layer 31 to the upper layer line in the cell part, which is not shown. Further, the fifth interlayer insulating film 24 is formed on the fourth interlayer insulating film 23.

As described above, in the second exemplary embodiment, by connecting the first conductive layer 31 and the second conductive layer 51 through the contact plug 71, it is possible to eliminate the step of performing deposition and etch back of the third conductive layer 61, which is performed in the first exemplary embodiment, thus enabling the fuse formation without any additional step.

### Third Exemplary Embodiment

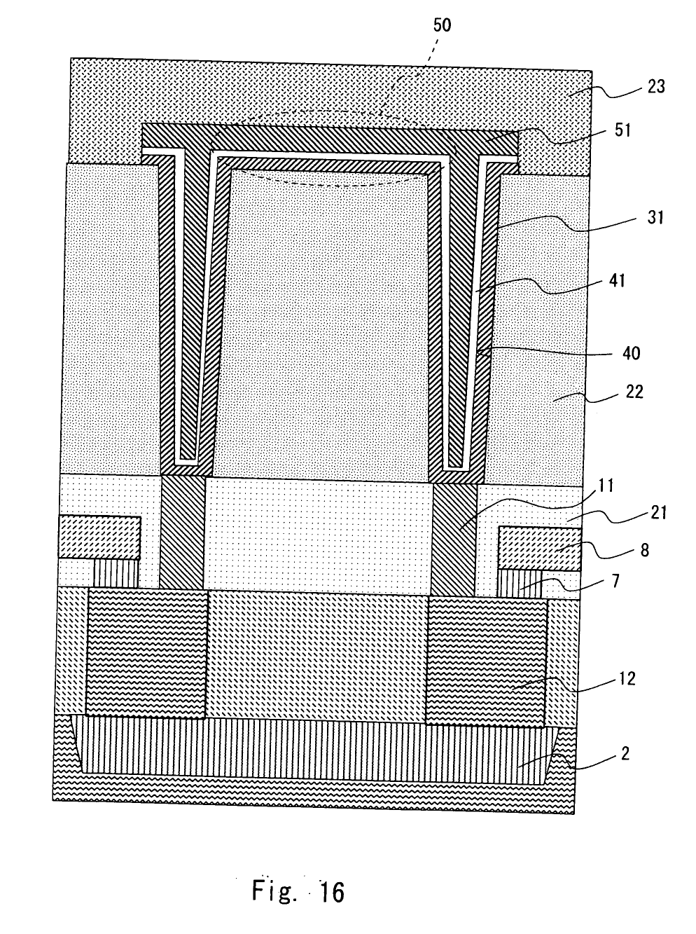

A semiconductor device according to a third exemplary embodiment of the present invention is described hereinafter. FIG. 15 is a plan view showing a fuse part of the semiconductor device according to the third exemplary embodiment of the present invention, and FIG. 16 is a cross-sectional view along line XVI-XVI in FIG. 15. A feature of the third exemplary embodiment is that the first conductive layer 31 to serve as the lower electrode in the cell part 101 functions as a fuse.

As shown in FIG. 16, the first conductive layer 31 is connected to the contact plug 11 at the bottom. The first conductive layer 31 is further connected to the bit line 8 through the contact plugs 12 and 7 and routed to a decision circuit. The first conductive layer 31 is covered with the second conductive layer 51. In the third exemplary embodiment, the first conductive layer 31 and the second conductive layer 51 are electrically isolated by the capacitor insulating film 41 and thus not connected to each other.

A method of manufacturing the semiconductor device having such a structure is described hereinafter. The process up to the step of forming the second interlayer insulating film 21 is the same as that in the first exemplary embodiment and thus not described. Firstly, the third interlayer insulating film 22 is deposited, and the second capacitor holes 40 are made in the same step as the first capacitor holes 52 of the cell part 101. Then, the first conductive layer 31 to serve as the lower electrode in the cell part 101 is deposited, and a photoresist is coated all over the substrate to fill the second capacitor holes 40. Although the photoresist is generally left only inside the capacitor hole by performing flood exposure and development, the photoresist is left in the fuse, the fuse lead part and inside the second capacitor holes 40 by using a mask pattern rather than performing flood exposure in this exemplary embodiment. After that, the first conductive layer 31 is separated by etch back.

Then, the capacitor insulating film 41 is formed by CVD, and the second conductive layer 51 (the upper electrode) is formed. In this step, the second conductive layer 51 of the fuse part is patterned so as to substantially overlap the first conductive layer 31 in the lower layer as shown in FIG. 15. Further, the fourth interlayer insulating film 23 is formed on the third interlayer insulating film 22. In the third exemplary embodiment, the first conductive layer 31 to function as the lower electrode is configured as a fuse. As shown in FIG. 16, in the semiconductor device according to the third exemplary embodiment, the fuse part 102 and the cell part 101 have substantially the same structure.

As described above, in the third exemplary embodiment, because the first conductive layer 31 to serve as the lower electrode is used as a fuse, there is no need to add any manufacturing step for forming the fuse. The fuse for replacing a defective bit of a memory cell thereby has the same structure as the memory cell, and it is thus possible to place the fuse on board at low costs.

### Fourth Exemplary Embodiment

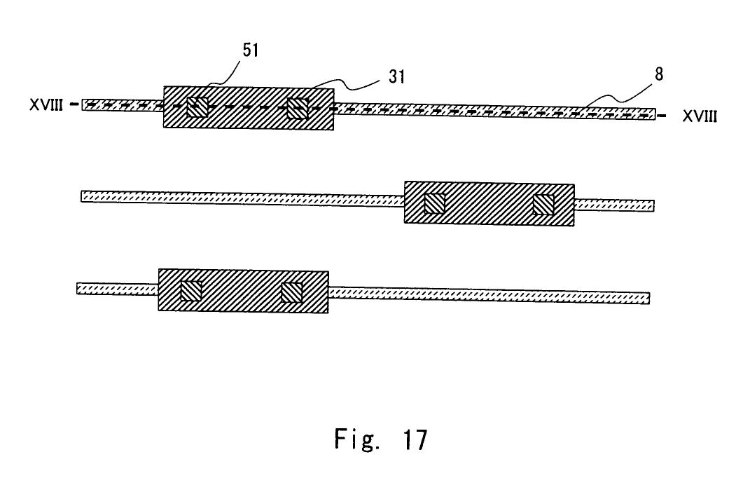

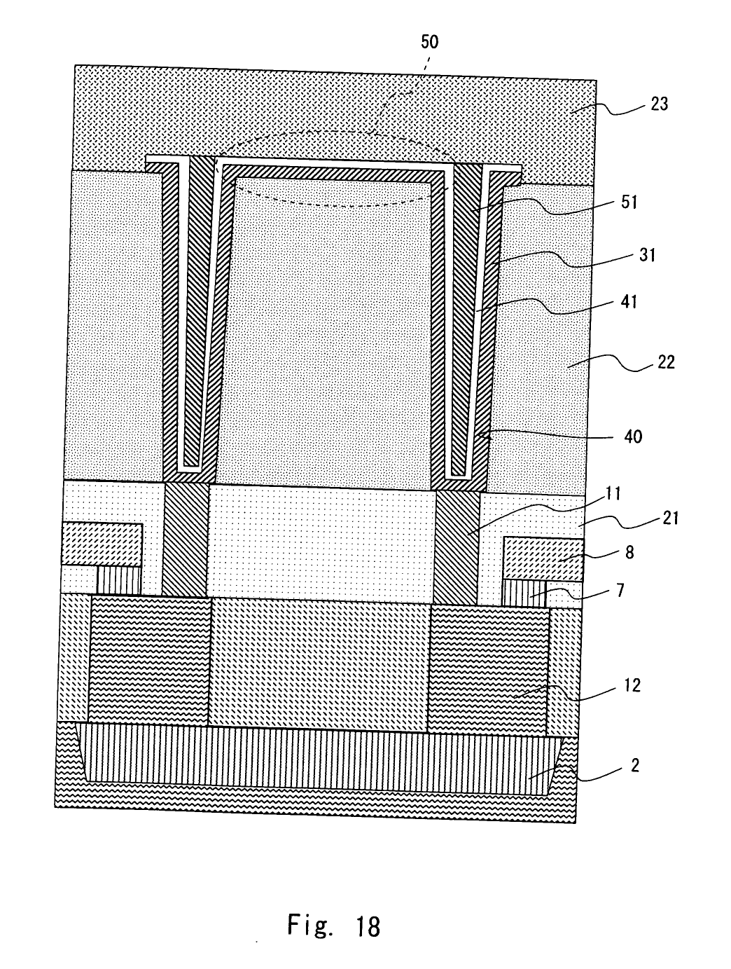

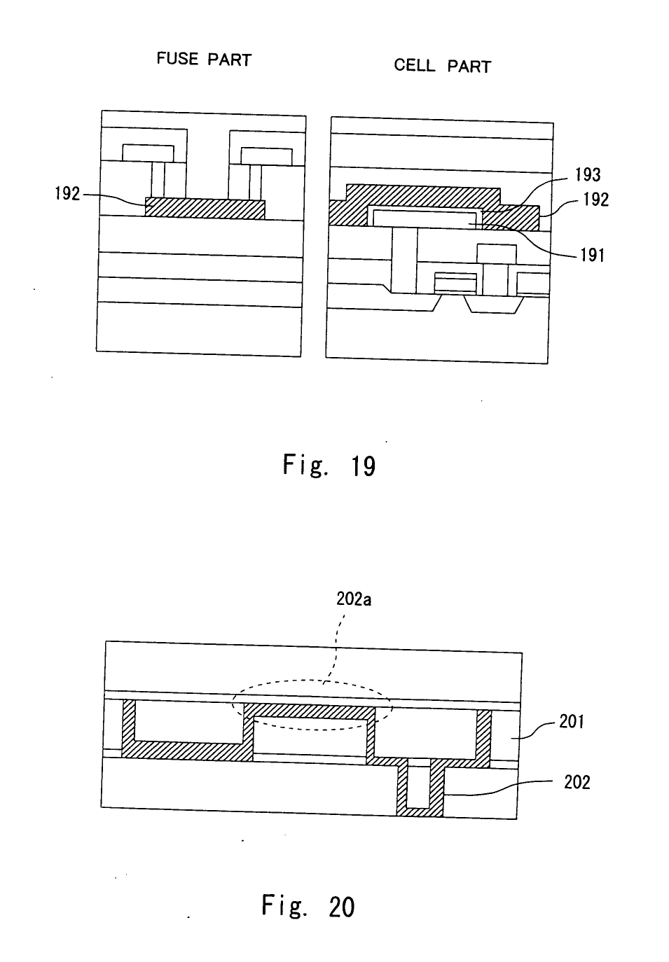

FIG. 17 is a plan view showing a fuse part of a semiconductor device according to a fourth exemplary embodiment of the present invention, and FIG. 18 is a cross-sectional view along line XVIII-XVIII in FIG. 17. A feature of the fourth exemplary embodiment is that the fuse 50 is formed in the first conductive layer 31 to serve as the lower electrode in the cell part 101, just like the third exemplary embodiment. However, the shape of the second conductive layer 51 (the upper electrode) is different from that of the third exemplary embodiment. In the fourth exemplary embodiment, only the first conductive layer 31 is formed between the adjacent second capacitor holes 40, and the second conductive layer 51 is not formed between the second capacitor holes 40.

A method of manufacturing the semiconductor device having such a structure is described hereinafter. The process up to the step of forming the second interlayer insulating film 21 is the same as that in the first exemplary embodiment and thus not described. Firstly, the third interlayer insulating film 22 is deposited, and the second capacitor holes 40 are made in the same step as the first capacitor holes 52 of the cell part 101. Then, the first conductive layer 31 to serve as the lower electrode is deposited, and a photoresist is coated all over the substrate to fill the second capacitor holes 40. Then, the photoresist is left inside the second capacitor hole 40 and on a part of the third interlayer insulating film 22 by using a mask pattern, and the first conductive layer 31 is formed by etch back.

Then, the capacitor insulating film 41 is formed by CVD, and the second conductive layer 51 (the upper electrode) is formed. In this step, the second conductive layer 51 of the fuse part is not patterned as shown in FIG. 17. The second conductive layer 51 is left inside the second capacitor hole 40 of the fuse part after etching.

As described above, the second conductive layer 51 in the fuse part 102 is not patterned in the semiconductor device according to the fourth exemplary embodiment, and it is thereby possible to further simplify the manufacturing process and reduce costs.

The above exemplary embodiments can be combined as desirable by one of ordinary skill in the art.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. A semiconductor device which includes a dynamic random access memory (DRAM) cell and a fuse comprising:
an insulating layer having a plurality of first capacitor holes and a plurality of second capacitor holes;
a capacitor function as the DRAM cell formed in the first capacitor holes; and
a fuse formed between the second capacitor holes.

2. The semiconductor device according to claim 1, wherein an interval between the second capacitor holes is larger than an interval between the first capacitor holes.

3. The semiconductor device according to claim 1,
wherein the capacitor includes a lower electrode and an upper electrode, and
the fuse includes at least one of a first conductive layer in the same layer as the lower electrode of the capacitor or a second conductive layer in the same layer as the upper electrode of the capacitor.

4. The semiconductor device according to claim 1,
wherein the capacitor comprises a lower electrode and an upper electrode, and
the fuse comprises a first conductive layer which is the same layer of the lower electrode of the capacitor, a second conductive layer which is the same layer of the upper electrode of the capacitor, and a third conductive layer that connects the first conductive layer and the second conductive layer,
wherein the first conductive layer is formed along internal surfaces of the second capacitor holes, and the second conductive layer is formed in the second capacitor hole and between the second capacitor holes, and
wherein a fuse cut portion is the second conductive layer formed between the second capacitor holes.

5. The semiconductor device according to claim 4, wherein the third conductive layer is a contact plug.

6. The semiconductor device according to claim 1,
wherein the capacitor comprises a lower electrode and an upper electrode, and
the fuse comprises a first conductive layer which is the same layer of the lower electrode of the capacitor, a second conductive layer which is the same layer of the upper electrode of the capacitor, and a third conductive layer that connects the first conductive layer and the second conductive layer,
wherein a first conductive layer is formed on internal surfaces of the second capacitor holes and between the second capacitor holes and a second conductive layer is formed above the first conductive layer on internal surfaces of the second capacitor holes and between the second capacitor holes, and
wherein a fuse cut portion is the first conductive layer and the second conductive layer formed between the second capacitor holes.

7. The semiconductor device according to claim 1, comprising:
wherein the capacitor comprises a lower electrode and an upper electrode, and
the fuse comprises a first conductive layer which is the same layer of the lower electrode of the capacitor, a second conductive layer which is the same layer of the upper electrode of the capacitor, and a third conductive layer that connects the first conductive layer and the second conductive layer,
wherein a first conductive layer is formed on internal surfaces of the second capacitor holes and between the second capacitor holes and a second conductive layer is formed above the first conductive layer inside the second capacitor holes, and
wherein a fuse cut portion is the first conductive layer formed between the second capacitor holes.

8. The semiconductor device according to claim 4, wherein the first conductive layer is a lead line of the fuse.

9. The semiconductor device according to claim 1, wherein adjacent fuses are disposed in a staggered arrangement.

10. A method of manufacturing a semiconductor device comprising:
forming an insulating layer on a semiconductor substrate;
making first capacitor holes and second capacitor holes in the insulating layer;
forming a capacitor in the first capacitor holes; and
forming a fuse by forming a conductive layer between the second capacitor holes.

11. The method of manufacturing a semiconductor device according to claim 10, wherein
the first capacitor holes and the second capacitor holes are made in the same step, and
the fuse is formed in the same step as forming at least one of an upper electrode and a lower electrode of the capacitor.
